(19) United States
(12) Patent Application Publication
(10) Pub. No.: US 2025/0143050 A1
(43) Pub. Date: May 1, 2025

(54) LIGHT-EMITTING DIODE, LIGHT-EMITTING DEVICE AND VEHICLE LAMP

(71) Applicant: QUANZHOU SANAN SEMICONDUCTOR TECHNOLOGY CO., LTD., Quanzhou (CN)

(72) Inventors: POYANG CHANG, Xiamen (CN); HAO DONG, Xiamen (CN); FANWEI LIN, Xiamen (CN); CHUNG-YING CHANG, Xiamen (CN)

(21) Appl. No.: 19/011,591

(22) Filed: Jan. 7, 2025

Related U.S. Application Data
(63) Continuation of application No. PCT/CN2022/126223, filed on Oct. 19, 2022.

(30) Foreign Application Priority Data
Jul. 7, 2022 (CN) 2022107934331

(51) Int. Cl. H10H 20/857

(52) U.S. Cl. CPC H10H 20/857

(57) ABSTRACT

A LED includes: a metal substrate including a first metal layer; a semiconductor layer sequence disposed on the metal substrate, where the semiconductor layer sequence includes a first semiconductor layer, a second semiconductor layer and an active layer disposed between the first semiconductor layer and the second semiconductor layer; a first electrode, electrically connected to the first semiconductor layer; and a second electrode, electrically connected to the second semiconductor layer. A side of the metal substrate facing away the semiconductor layer sequence defines a groove, a second metal layer is disposed in the groove, the metal substrate includes a groove edge which is protruded, and the groove edge is no more than 0.5 μm higher than the second metal layer, enhancing the reliability of the LED in the packaged bonding product.

### CROSS-REFERENCE TO RELATED APPLICATIONS

This application is a continuation of International Patent Application No. PCT/CN2022/126223, filed on Oct. 19, 2022, which claims the priority of Chinese Patent Application No. 202210793433.1, filed on Jul. 7, 2022, both of which are herein incorporated by reference in their entirety.

### TECHNICAL FIELD

The disclosure relates to the field of semiconductor optoelectronics technologies, and more particularly to a semiconductor light-emitting chip grown on a substrate, and a preparation method and a process thereof.

### BACKGROUND

Existing semiconductor light-emitting chips use silicon as a carrier substrate. During the processing of the silicon substrate, especially during laser cutting, scoring, grinding, and polishing, the silicon substrate is susceptible to brittle fracture due to the impact of the processing, which may lead to subsurface cracks causing defective products to be shipped, resulting in customer complaints. A back gold layer or a back gold-tin layer is provided on a back side of the silicon substrate. During laser cutting, a sintered mark of 2 micrometers (μm) to 8 μm will be produced, and there will be phenomena such as poor chip bonding during packaging, due to an uneven surface.

In processes in the related art, a wheel knife is used to remove the sintered mark, which is time-consuming and prone to breakage and subsurface cracks. On average, it takes 1.3 hours to cut one piece, significantly increasing production costs. The current ultra-vertical process is gradually changing from the silicon substrate to a metal substrate, which can greatly reduce the risks associated with the use of the silicon substrate, such as the likelihood of the subsurface cracks. However, during the processing of the metal substrate in the chip manufacturing process, laser scoring and cutting are involved. After laser scoring and cutting, there will be noticeable sintered body, and a protruding part of the sintered body can cause poor contact during use, leading to increased voltage, aging, and dead lights.

### SUMMARY

In order to solve problems mentioned in the background, the disclosure provides a light-emitting diode (LED). The LED includes a metal substrate, a semiconductor layer sequence disposed on the metal substrate, a first electrode, and a second electrode. The semiconductor layer sequence includes a first semiconductor layer, a second semiconductor layer and an active layer, and the active layer is disposed between the first semiconductor layer and the second semiconductor layer. The first electrode is electrically connected to the first semiconductor layer, and the second electrode is electrically connected to the second semiconductor layer. The metal substrate includes a first metal layer.

A side of the metal substrate facing away the semiconductor layer sequence defines a groove, which is a part of the metal substrate itself. A second metal layer is disposed in the groove, the metal substrate includes a groove edge which is extended and protruded, and the groove edge is no more than 0.5 μm higher than the second metal layer. The term “no more than” refers to an overall height comparison between the groove edge and the second metal layer. If a height difference exceeds 0.5 μm, there will be eutectic bonding issues. The groove edge is a bottom edge of the metal substrate.

In an embodiment, a height of the groove edge is lower than a height of the second metal layer, and the second metal layer is configured to be a primary bonding contact surface to enhance the contact effect and eliminate the problem of poor contact.

In an embodiment, the first metal layer has a first Mohs hardness, the second metal layer has a second Mohs hardness, the first Mohs hardness is greater than the second Mohs hardness, and the second Mohs hardness is in a range of 0.92 to 3. The hardness levels are designed to protect the semiconductor layer sequence.

In an embodiment, the first metal layer includes one or alloy selected from the group consisting of molybdenum, copper with a Mohs hardness of 3, tungsten, iron, aluminum, titanium, nickel and cobalt. A Mohs hardness of the molybdenum is in a range of 5 to 5.5, the Mohs hardness of the copper is 3, and a Mohs hardness of the iron is in a range of 4 to 5.

In an embodiment, the second metal layer includes one or alloy selected from the group consisting of gold, gold-tin, indium and tin. A Mohs hardness of the gold is in a range of 2.5 to 3, a Mohs hardness of the indium is in a range of 0.92 to 1.2, and a Mohs hardness of the tin is in a range of 1.8 to 2.

In an embodiment, the groove edge of the metal substrate is obtained by laser cutting, which means that either laser front cutting or laser back cutting can be used in a projection direction, and the groove edge is disposed on a cutting path of a chip.

In an embodiment, the groove edge includes the first metal layer, a melting point of the first metal layer is greater than a melting point of the second metal layer, the melting point of the first metal layer is greater than 500 degrees Celsius (° C.), and the melting point of the second metal layer is less than 350° C. The melting point characteristics are used to control the bonding quality.

In an embodiment, a thickness of the first metal layer is in a range of 80 μm to 200 μm, and a thickness of the second metal layer is in a range of 0.1 μm to 10 μm. If the thickness of the first metal layer is less than 80 μm, wafer warpage will occur, leading to a decrease in processing accuracy. If the first metal layer is too thick, production costs will increase. The thickness of the second metal layer is in a range of 0.1 μm to 10 μm, which offers optimal bonding characteristics.

In another aspect, the disclosure provides a LED. The LED includes: a substrate, a semiconductor layer sequence disposed on the substrate, a first electrode, a second electrode and a first metal layer. The semiconductor layer sequence includes a first semiconductor layer, a second semiconductor layer and an active layer, and the active layer is disposed between the first semiconductor layer and the second semiconductor layer. The first electrode is electrically connected to the first semiconductor layer, the second electrode is electrically connected to the second semiconductor layer, and the first metal layer is disposed under the substrate.

A side of the first metal layer facing away the semiconductor layer sequence defines a groove, a second metal layer is disposed in the groove, the first metal layer includes a groove edge which is protruded, and the groove edge is no more than 0.5 μm higher than the second metal layer.

In an embodiment, a thickness of the first metal layer is in a range of 0.1 μm to 10 μm, and a thickness of the second metal layer is in a range of 0.1 μm to 10 μm.

The disclosure further provides a light-emitting device. The light-emitting device includes a base serving as a support and a LED bonded to the base. The LED includes a metal substrate and a semiconductor layer sequence disposed on the metal substrate. The semiconductor layer sequence includes a first semiconductor layer, a second semiconductor layer and an active layer, and the active layer is disposed between the first semiconductor layer and the second semiconductor layer. The LED further includes: a first electrode, electrically connected to the first semiconductor layer; and a second electrode, electrically connected to the second semiconductor layer. The metal substrate includes a first metal layer. A side of the metal substrate facing away the semiconductor layer sequence defines a groove, and a second metal layer is disposed in the groove. On a side of the first metal layer and the second metal layer facing away from the semiconductor layer sequence, the second metal layer is directly or indirectly bonded to the base, the metal substrate includes a groove edge which is protruded, and the groove edge is no more than 0.1 μm higher than the second metal layer.

The disclosure further provides a light-emitting device. The light-emitting device includes a base serving as a support and a LED bonded to the base. The LED includes a metal substrate and a semiconductor layer sequence disposed on the metal substrate. The semiconductor layer sequence includes a first semiconductor layer, a second semiconductor layer and an active layer, and the active layer is disposed between the first semiconductor layer and the second semiconductor layer. The LED further includes: a first electrode, electrically connected to the first semiconductor layer; and a second electrode, electrically connected to the second semiconductor layer. The metal substrate includes a first metal layer. A side of the metal substrate facing away the semiconductor layer sequence defines a groove, and a second metal layer is disposed in the groove. On a side of the first metal layer and the second metal layer facing away from the semiconductor layer sequence, the LED is bonded to the base through a bonding layer, the metal substrate includes a groove edge which is protruded, and the groove edge is no more than 0.1 μm higher than the second metal layer.

The disclosure further provides a vehicle lamp, including any one of the above light-emitting devices.

The beneficial effects of the present disclosure include enhancing the bonding contact force of the LED in a packaged device, reducing the device voltage, and improving product reliability. Other beneficial effects of the disclosure are specifically described in the embodiments.

### BRIEF DESCRIPTION OF DRAWINGS

FIG. 1 to FIG. 3 illustrate schematic cross-sectional diagrams of a LED according to a first embodiment of the disclosure.

FIG. 4 illustrates a schematic cross-sectional diagram of a LED according to a second embodiment of the disclosure.

FIG. 5 illustrates a schematic cross-sectional diagram of a LED according to a third embodiment of the disclosure.

FIG. 6 illustrates a schematic cross-sectional diagram of a LED according to a fourth embodiment of the disclosure.

FIG. 7 to FIG. 13 illustrate schematic flowcharts of a LED according to a fifth embodiment of the disclosure.

FIG. 14 illustrates a schematic cross-sectional diagram of a LED according to a sixth embodiment of the disclosure.

FIG. 15 illustrates a schematic cross-sectional diagram of a LED according to a seventh embodiment of the disclosure.

FIG. 16 illustrates a schematic cross-sectional diagram of a LED according to an eighth embodiment of the disclosure.

FIG. 17 illustrates a schematic cross-sectional diagram of a LED according to a ninth embodiment of the disclosure.

### DESCRIPTION OF REFERENCE SIGNS

100: semiconductor layer sequence; 100′: side wall; 110: first semiconductor layer; 120: second semiconductor layer; 130: active layer; 200: connecting layer; 210: first electrical connecting layer; 220: second electrical connecting layer; 221: transparent conductive layer; 222: metal reflective layer; 223: metal connecting layer; 300: insulating layer; 310: first insulating layer; 320: second insulating layer; 330: third insulating layer; 410: first electrode; 420: second electrode; 421: wire; 501: protrusion; 510: first metal layer; 520: second metal layer; 521: first part; 522: second part; 600: bonding layer; 700: cover; 810: first pad; 820: second pad;

C: cutting path; D1: height difference; D2: depth of groove; D3: thickness of groove edge; D4: width of groove; D5: width of part of first metal layer at edge of second metal layer; G1: groove; G11: groove edge; G2: recess; S1: metal substrate; S2: insulating substrate; S3: growth substrate; S4: base; S41: insulating support; S42: conductive support; S421: first conductive support; S422: second conductive support.

### DETAILED DESCRIPTION OF EMBODIMENTS

In conjunction with the accompanying drawings, further explanation of the disclosure is provided below.

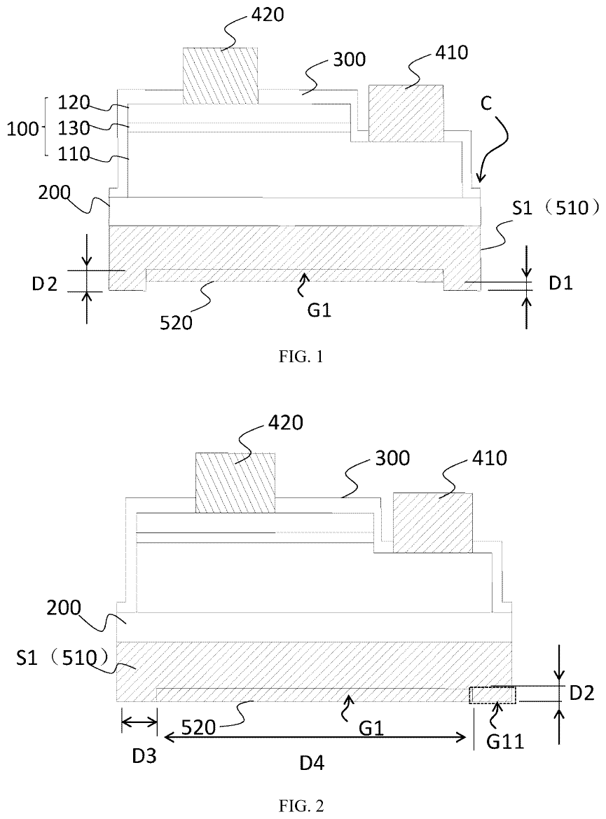

In a first embodiment of the disclosure, referring to FIG. 1 and FIG. 2, a LED includes a metal substrate S1, and a semiconductor layer sequence 100 disposed on the metal substrate S1, arranged sequentially from bottom to top. In some implementations, a bonding metal and/or an insulating dielectric film as a connecting layer 200 may be disposed between the metal substrate S1 and the semiconductor layer sequence 100. The semiconductor layer sequence 100 includes a first semiconductor layer 110, a second semiconductor layer 120 and an active layer 130, and the active layer 130 is disposed between the first semiconductor layer 110 and the second semiconductor layer 120. An insulating layer 300 covers an outer surface of the semiconductor layer sequence 100. The LED further includes a first electrode 410 and a second electrode 420. The first electrode 410 is electrically connected to the first semiconductor layer 110, and the second electrode 420 is electrically connected to the second semiconductor layer 120. The metal substrate S1 includes a first metal layer 510.

A side of the semiconductor layer sequence 100 facing away the metal substrate S1 is a front side of the semiconductor layer sequence 100, provided with a window part serving as an N-type opening, and the window part penetrates through the second semiconductor layer 120 and the active layer 130, and is used for creating an N-type electrode. The window part can also penetrate a part of the first semiconductor layer 110, exposing the first semiconductor layer 110. An upper surface of an exposed part of the first semiconductor layer 110 forms a first platform, and the first electrode 410 is disposed on the first platform. An upper surface of the second semiconductor layer 120 forms a second platform, and the second electrode 420 is disposed on the second platform.

A side of the metal substrate S1 facing away the semiconductor layer sequence 100 is concave inward to define a groove G1. The groove G1 is defined at a central area of the metal substrate S1, which means that the groove G1 is a part of the metal substrate S1 itself. A second metal layer 520 is disposed in the groove G1. The metal substrate S1 includes a groove edge G11 which is extended and protruded. The groove edge G11 in this embodiment is continuous and is no more than 0.5 μm higher than the second metal layer 520, i.e., a height difference D1 between the groove edge G11 and the second metal layer 520 is not greater than 0.5 μm. If it exceeds 0.5 μm, it would surpass a bonding allowance range, leading to voids in a bonding area with external circuits. The groove edge G11 partially or fully coincides with a bottom edge of the metal substrate S1 on a projection plane. A depth D2 of the groove G1 is in a range of 0.1 μm to 10 μm. In this embodiment, the depth D2 of the groove G1 is adopted in a range of 0.1 μm to 5 μm, which is conducive to setting a thickness of the second metal layer 520 and ensuring the bonding contact effect within this dimension. A thickness D3 of the groove edge G11 is in a range of 1 μm to 20 μm. In this embodiment, a width D4 of the groove G1 is a chip width minus the thickness D3 of the groove edge G11. Considering the thickness D3 of the groove edge G11 and the dimensions of the metal substrate S1, the metal substrate S1, for example, can be rectangular with a single side dimension greater than 400 μm.

The groove G1 is concave inward to form a planar contact surface with the second metal layer 520, a side of the second metal layer 520 close to the metal substrate S1 is a front side, and a side of the second metal layer 520 facing away the metal substrate S1 is a back side, i.e., in FIGs, an upper direction is the front side and a lower direction is the back side. A side surface of the second metal layer 520 is disposed between the front side and the back side.

The metal substrate S1 includes a groove edge G11 which is extended, and the groove edge G11 and the second metal layer 520 together form a side contact surface. The planar contact surface and the side contact surface together completely or partially cover the front side and the side surface of the second metal layer 520. In this embodiment, the planar contact surface and the side contact surface together completely cover the front side and the side surface of the second metal layer 520.

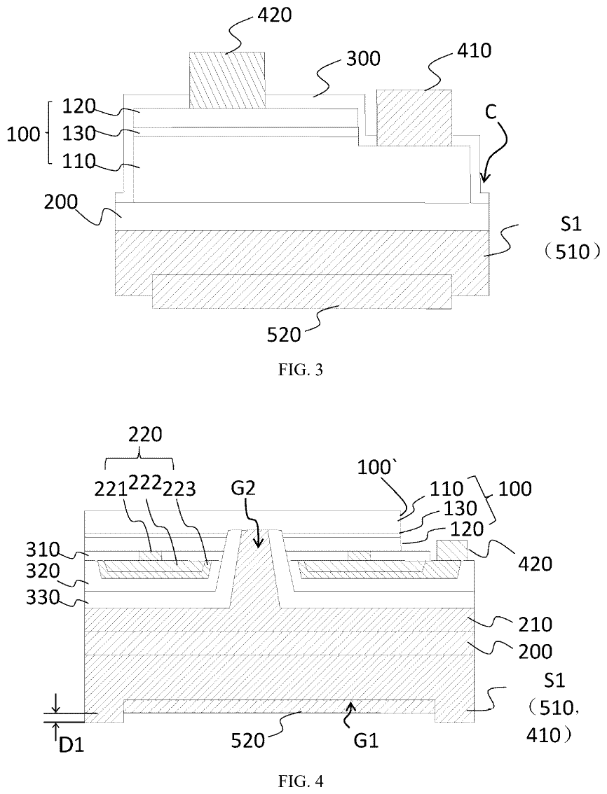

Referring to FIG. 3, in some implementations of the first embodiment, a height of the groove edge G11 is lower than a height of the second metal layer 520, and for example, the back side of the second metal layer 520 is 0 μm to 0.5 μm higher than the groove edge G11. In a subsequent packaging process, the second metal layer 520 is used as a primary bonding contact surface, and the side surface of the second metal layer 520 serves as an auxiliary contact surface, enhancing the contact effect, eliminating poor contact issues, and reducing or avoiding the obstruction of bonding by the groove edge G11.

Referring to FIG. 2 of this embodiment, the side contact surface is at a same height as the side surface of the second metal layer 520, without covering the back side of the second metal layer 520, and the back side of the second metal layer 520 is exposed.

In this embodiment, the first metal layer 510 has a first Mohs hardness, the second metal layer 520 has a second Mohs hardness, the first Mohs hardness is greater than the second Mohs hardness, and the second Mohs hardness is in a range of 0.92 to 3. Under the first Mohs hardness, the first metal layer 510 serves to protect the semiconductor layer sequence 100. For example, the first metal layer 510 includes one or more selected from the group consisting of molybdenum, copper, tungsten, iron, aluminum, titanium, nickel and cobalt, where as an exemplary material, the first Mohs hardness is not less than 2 and greater than the second Mohs hardness. A Mohs hardness of the molybdenum is in a range of 5 to 5.5, a Mohs hardness of the copper is 3, and a Mohs hardness of the iron is in a range of 4 to 5. The second metal layer 520 includes one or more selected from the group consisting of gold, gold-tin, indium and tin. A Mohs hardness of the gold is in a range of 2.5 to 3, a Mohs hardness of the indium is in a range of 0.92 to 1.2, and a Mohs hardness of the tin is in a range of 1.8 to 2. In this embodiment, the groove edge G11 includes the first metal layer 510. A melting point of the first metal layer 510 is greater than a melting point of the second metal layer 520, the melting point of the first metal layer 510 is greater than 500° C., and the melting point of the second metal layer 520 is less than 350° C. The melting point characteristics are used to create a reliable height difference and control the bonding quality, this embodiment is particularly suitable for material systems where the first metal layer 510 has a high melting point.

In this embodiment, a thickness of the first metal layer 510 is in a range of 80 μm to 200 μm, and a thickness of the second metal layer 520 is in a range of 0.1 μm to 10 μm. If the thickness of the first metal layer 510 is less than 80 μm, wafer warpage will occur, leading to a decrease in processing accuracy. If the first metal layer 510 is too thick, production costs will increase. The thickness of the second metal layer 520 is in a range of 0.1 μm to 10 μm, which offers optimal bonding characteristics.

In this embodiment, an edge of the LED is provided with a cutting path C that is to be laser-cut. The groove edge G11 of the metal substrate S1 is laser-cut, which means that, when viewed in the projection direction, the groove edge G11 is positioned on the cutting path C of the chip, which is used in the process of dicing the wafer into individual die for separation.

In this embodiment, the side contact surface between the first metal layer 510 and the second metal layer 520 partially covers the side surface of the second metal layer 520, and an uncovered part of the side surface of the second metal layer 520 and the back side of the second metal layer 520 are exposed.

In a second embodiment of the disclosure, referring to FIG. 4, a LED with a super vertical structure includes a semiconductor layer sequence 100 as an epitaxial structure, with a side wall 100′, and a first surface and a second surface which are relatively arranged. The first surface is a front side, and the second surface is a back side. The semiconductor layer sequence 100 includes a first semiconductor layer 110, a second semiconductor layer 120 and an active layer 130. The first semiconductor layer 110 and a second semiconductor layer 120 are arranged sequentially between the first and second surfaces, and the active layer 130 is disposed between the first semiconductor layer 110 and a second semiconductor layer 120, configured to produce radiative light emission. The LED further includes a first electrical connecting layer 210, electrically connected to the first semiconductor layer 110; and a second electrical connecting layer 220, electrically connected to the second semiconductor layer 120. The second surface defines one or multiple recesses G2. The recess G2 at least penetrates through the second semiconductor layer 120, the active layer 130, and a part of the first semiconductor layer 110. A first insulating layer 310 extends from the recess G2 to the second surface. The first electrical connecting layer 210 forms a protrusion within the recess G2 and electrically connected to the first semiconductor layer 110 through the recess G2. The first insulating layer 310 and a second insulating layer 320 are configured to electrically isolate the first electrical connecting layer 210 and the second electrical connecting layer 220, the first electrical connecting layer 210 and/or the second electrical connecting layer 220 include metal. The LED has a single side dimension no less than 600 μm.

In this embodiment, the metal substrate S1 serves as a first electrode 410, and is electrically connected to the first electrical connecting layer 210. An upper surface of the second electrical connecting layer 220 is provided with a second electrode 420. The first electrode 410 and the second electrode 420 are configured to connect with external circuits. The second electrical connecting layer 220 includes a transparent conductive layer 221 configured to be in contact with the semiconductor layer sequence 100, a metal reflective layer 222, and a metal connecting layer 223. The metal substrate S1 includes a first metal layer 510. A connecting layer 200 is disposed between the metal substrate S1 and the first electrical connecting layer 210.

In this embodiment, a side of the metal substrate S1 facing away the semiconductor layer sequence 100 defines a groove G1. The groove G1 is defined at a central area of the metal substrate S1, which means that the groove G1 is a part of the metal substrate S1 itself. A second metal layer 520 is disposed in the groove G1. The metal substrate S1 includes a groove edge G11 which is protruded. The second metal layer 520 adopts gold-tin. The groove edge G11 in this embodiment is continuous. The first metal layer 510 of the groove edge G11 is no more than 0.5 μm higher than the second metal layer 520, i.e., a height difference D1 between the first metal layer 510 and the second metal layer 520 is not greater than 0.5 μm. An outer edge of the groove G1 coincides with an edge of the metal substrate S1, either partially or entirely.

In some implementations of this embodiment, the second metal layer 520 includes gold and gold-tin. In the manufacturing processing, the gold is disposed between the metal substrate S1 and the gold-tin.

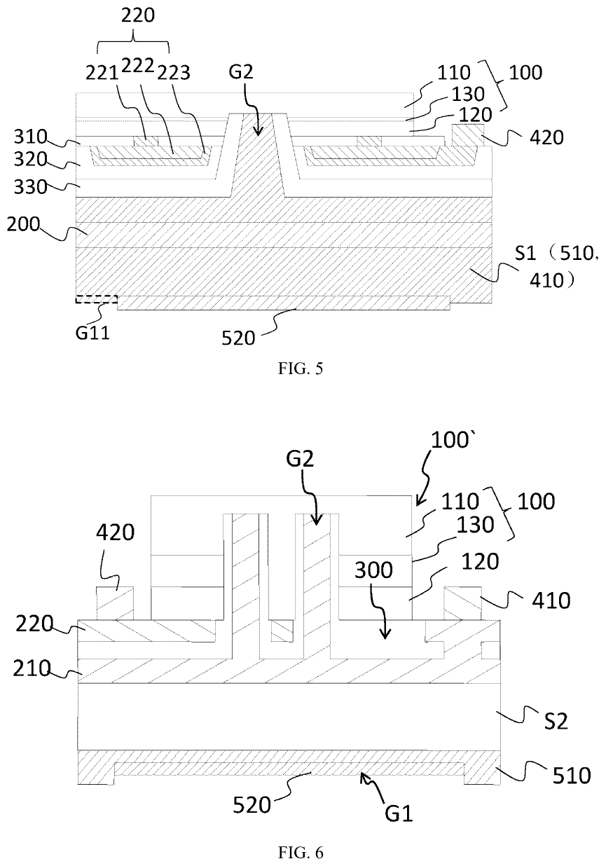

In a third embodiment, referring to FIG. 5, the difference from the second embodiment is that, the height of the groove edge G11 is lower than the height of the second metal layer 520. The second metal layer 520 is 0.1 μm to 1 μm higher than the groove edge G11. In the downstream packaging process, the second metal layer 520 is used as the primary bonding contact surface to enhance the contact effect, eliminate poor contact issues, and reduce or avoid the obstruction of bonding caused by the groove edge G11.

In a fourth embodiment of the disclosure, referring to FIG. 6, a LED as a horizontal-vertical chip product is provided, including: a semiconductor layer sequence 100. The semiconductor layer sequence 100 includes a first semiconductor layer 110, a second semiconductor layer 120 and an active layer 130. The active layer 130 is disposed between the first semiconductor layer 110 and the second semiconductor layer 120, and configured to produce radiation. The first semiconductor layer 110 is disposed at the front side of the semiconductor layer sequence 100. The semiconductor layer sequence 100 incudes at least one recess G2, with a side wall covered by an insulating layer 300. The recess G2 extends from the back side of the semiconductor layer sequence 100, which is opposite to the front side, through the active layer 130 to the first semiconductor layer 110. The LED further includes a first electrode 410 and a second electrode 420. The first electrode 410 is electrically connected to a first electrical connecting layer 210, and the second electrode 420 is electrically connected to a second electrical connecting layer 220. The first electrode 410 is electrically connected to the first semiconductor layer 110 by the first electrical connecting layer 210 passing through the recess G2. The first electrical connecting layer 210 and the second electrical connecting layer 220 are electrically insulated from each other by the insulating layer 300 extending through the recess G2. The first electrical connecting layer 210 and the second electrical connecting layer 220 are disposed on the back side of the semiconductor layer sequence 100; where the first electrical connecting layer 210 on the back side of the semiconductor layer sequence 100 mainly refers to a part excluding a part of the first electrical connecting layer 210 within the recess G2. The second electrical connecting layer 220 is in direct contact with the back side of the second semiconductor layer 120.

The LED further includes an insulating substrate S2, configured to support and dissipate heat. The insulating substrate S2 is not a growth substrate on which the semiconductor layer sequence 100 is epitaxially grown, but rather an independent support element. In the aforementioned structure, the semiconductor layer sequence 100 has no growth substrate. The term “no growth substrate” indicates that the growth substrate used for growth when needed is removed from the semiconductor layer sequence 100 or at least significantly thinned. In this embodiment, the insulating substrate S2 can be made of a ceramic substrate with good thermal dissipation capabilities.

The first electrical connecting layer 210 is connected to the front side of the insulating substrate S2. A contact area between the first electrical connecting layer 210 and the back side of the first semiconductor layer 110 is greater than 1.5% of an area of the first semiconductor layer 110. The first electrical connecting layer 210 is at least partially exposed on the front side to place the first electrode 410, and the second electrical connecting layer 220 is at least partially exposed on the front side to place the second electrode 420. The exposed parts of the first electrical connecting layer 210 and the second electrical connecting layer 220 are at the same height. This equal-height design allows for the creation of a bonding window by simply removing the semiconductor layer sequence 100 down to the first electrical connecting layer 210, without the need to etch through the insulating layer 300 or metal layers, which are more difficult to remove. This shortens the process cycle and improves process reliability. For example, it avoids issues such as inductively coupled plasma (ICP) ion beam-assisted radical etching, which could cause short circuits by etching metal onto the side wall 100′ of the semiconductor layer sequence 100, or the low efficiency of wet etching of metal and the insulating layer 300. The insulating layer 300 extending from the recess G2 covers the first electrical connecting layer 210 and the back side of the second electrical connecting layer 220, indicating that at least part of the back side of the second electrical connecting layer 220 is covered by the insulating layer 300. In some embodiments, the back side of the second electrical connecting layer 220 can be completely covered by the insulating layer 300. The second electrical connecting layer 220, especially the first electrical connecting layer 210, can be multi-layered in the vertical direction, and there may be structures where the front side is covered by the insulating layer 300. The first electrode 410 and the second electrode 420 are oriented towards the front side. In the embodiment of the disclosure, the second electrical connecting layer 220 is entirely covered on the front side of the insulating layer 300. The first electrode 410 and the second electrode 420 refer to electrical contact areas, such as bonding pads, suitable for electrical contact with the body of the LED from the front side. The first electrode 410 and the second electrode 420 are made on the same plane, meaning that the exposed parts of the first electrical connecting layer 210 and the second electrical connecting layer 220, which serve as windows for electrode fabrication, are on the same plane. This facilitates the overall structure fabrication, simplifies the process, and allows for the creation of equal-height electrodes. Unequal-height electrodes would increase the difficulty and reduce the efficiency of bonding. The first electrode 410 and the second electrode 420 are disposed on the side of the semiconductor layer sequence 100, avoiding the obstruction radiation and radiation efficiency reduction that would occur if the first electrode 410 and/or the second electrode 420 were disposed on top of the semiconductor layer sequence 100, thereby facilitating bonding. The first electrode 410 is designed to be electrically connected to the front side of the first electrical connecting layer 210, and similarly, the second electrode 420 is designed to be electrically connected to the front side of the second electrical connecting layer 220.

Advantageously, the first electrical connecting layer 210 is connected to the insulating substrate S2 and the first semiconductor layer 110, forming an effective thermal conduction path that directs heat from the first semiconductor layer 110 to the insulating substrate S2. Since the radiation from multiple quantum wells is emitted through the first semiconductor layer 110, heat tends to accumulate in the first semiconductor layer 110. In this embodiment, the first electrical connecting layer 210 effectively dissipates heat from the first semiconductor layer 110 to the insulating substrate S2.

In this embodiment, a side of the insulating substrate S2 facing away the semiconductor layer sequence 100 is provided with a first metal layer 510, i.e., the first metal layer 510 is disposed under the insulating substrate S2. A side of the first metal layer 510 facing away the semiconductor layer sequence 100 defines a groove G1. A second metal layer 520 is disposed in the groove G1. The first metal layer 510 includes a groove edge G11 which is protruded. The groove edge G11 is no more than 0.5 μm higher than the second metal layer 520. The first metal layer 510 adopts gold, and has a thickness in a range of 0.1 μm to 10 μm. A thickness of the second metal layer 520 is in a range of 0.1 μm to 10 μm. The first metal layer 510 has a first Mohs hardness, the second metal layer 520 has a second Mohs hardness, the first Mohs hardness is greater than the second Mohs hardness, and the second Mohs hardness is in a range of 0.92 to 3. Exemplarily, the first metal layer 510 includes one or more selected from the group consisting of molybdenum, copper, tungsten, iron, aluminum, titanium, nickel and cobalt. The second metal layer 520 includes one or more selected from the group consisting of gold, gold-tin, indium and tin.

In a fifth embodiment of the disclosure, a preparation method of a LED includes the following steps.

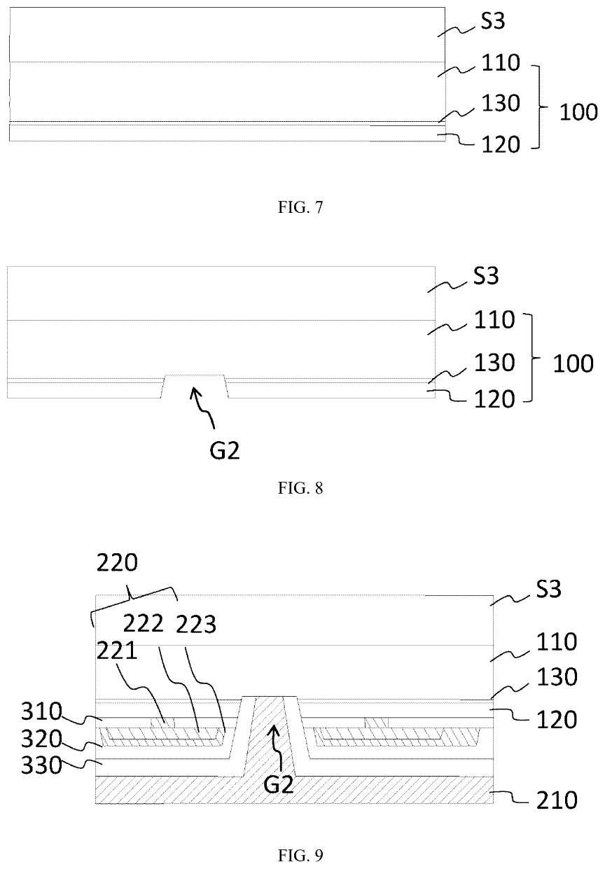

Step 1: referring to FIG. 7, a semiconductor layer sequence 100 is made on a growth substrate S3 to form a semiconductor wafer. The growth substrate S3 can be, for example, a sapphire wafer. The semiconductor layer sequence 100 includes: a first semiconductor layer 110 and a second semiconductor layer 120 arranged sequentially, and an active layer 130 disposed between the first semiconductor layer 110 and the second semiconductor layer 120.

Step 2: referring to FIG. 8, one or multiple recesses G2 are made on a side of the semiconductor layer sequence 100 facing away the growth substrate S3. For example, a part of the semiconductor layer sequence 100 is removed, and in an opening area of the recess G2, the second semiconductor layer 120 and the active layer 130 are removed to expose the first semiconductor layer 110. The recess G2 can be slot-shaped or hole-shaped.

Step 3: referring to FIG. 9, a first insulating layer 310 with one or multiple conductive holes is made on the side of the semiconductor layer sequence 100 facing away the growth substrate S3. A transparent conductive layer 221 is made within the conductive holes and/or on the side of the first insulating layer 310 facing away from the semiconductor layer sequence 100. A surface of the transparent conductive layer 221 can be covered with a metal reflective layer 222 and/or a metal connecting layer (i.e., a metal barrier layer) 223. In this embodiment, the transparent conductive layer 221 is sequentially covered with the metal reflective layer 222 and the metal connecting layer 223. The transparent conductive layer 221, the metal reflective layer 222, and the metal connecting layer 223 together form a second electrical connecting layer 220. The surface of the metal connecting layer 223 is covered with a second insulating layer 320, which extends to an edge of the recess G2. The surface of the second insulating layer 320 and the side wall of the recess G2 are covered with a third insulating layer 330, and the third insulating layer 330 is covered with a first electrical connecting layer 210.

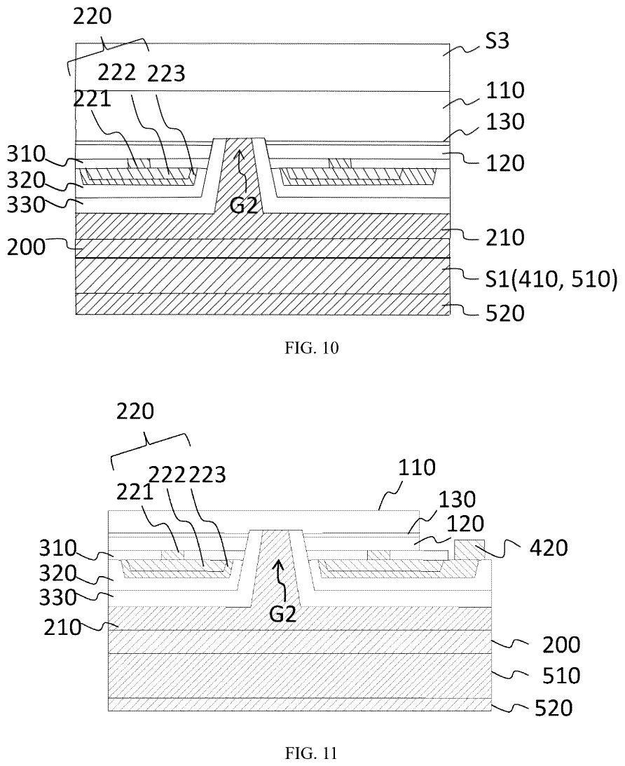

Step 4: referring to FIG. 10, the first electrical connecting layer 210 is bonded to a metal substrate S1 through a connecting layer 200. The metal substrate S1 includes a first metal layer 510, and a second metal layer 520 is made on a side of the metal substrate S1 facing away the semiconductor layer sequence 100, where the first metal layer 510 serves as a part of the first electrode 410.

Step 5: referring to FIG. 11, the growth substrate S3 and a part of the semiconductor layer sequence 100 are removed to expose a part of the first insulating layer 310 and the second electrical connecting layer 220 from the front side, and a second electrode 420 is made on the second electrical connecting layer 220.

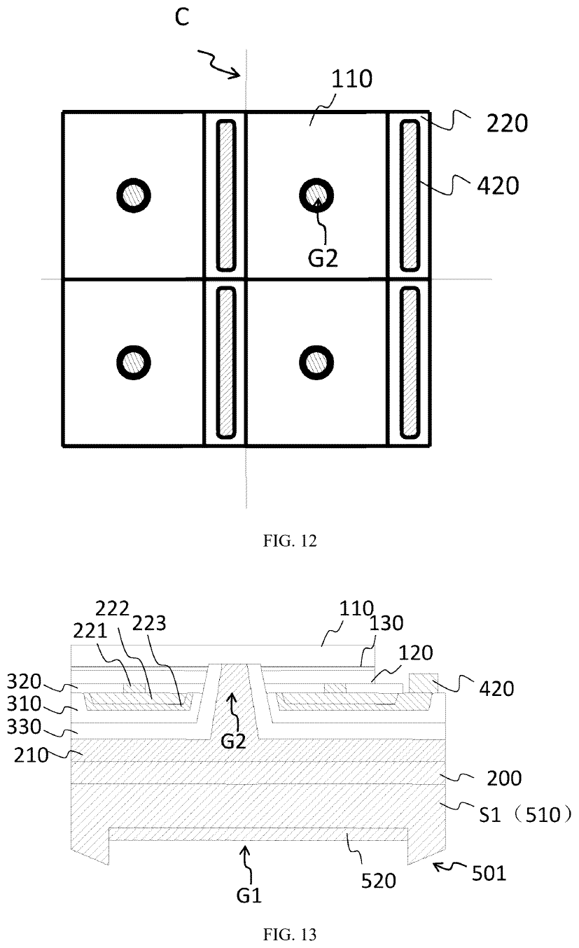

Step 6: referring to FIG. 12 and FIG. 13, laser cutting is performed on a pre-cutting path of the semiconductor wafer to divide the semiconductor wafer into multiple chips. The figure illustrations in this embodiment are for illustrative purposes only. The cutting combines horizontal and vertical directions, and by controlling the laser power used for cutting, a groove G1 is defined and a protrusion 501 is formed at an edge of the chip.

Step 7: referring to FIG. 4, a part of the protrusion 501 is removed through grinding and polishing. The first metal layer 510 at a groove edge G11 is no more than 0.5 μm higher than the second metal layer 520 (with a height difference D1 not greater than 0.5 μm). In actual processes, due to high-temperature fusion, the groove edge G11 may simultaneously have materials from the first metal layer 510 and the second metal layer 520. The outer edge of the groove G1 partially or fully coincides with the edge of the metal substrate S1.

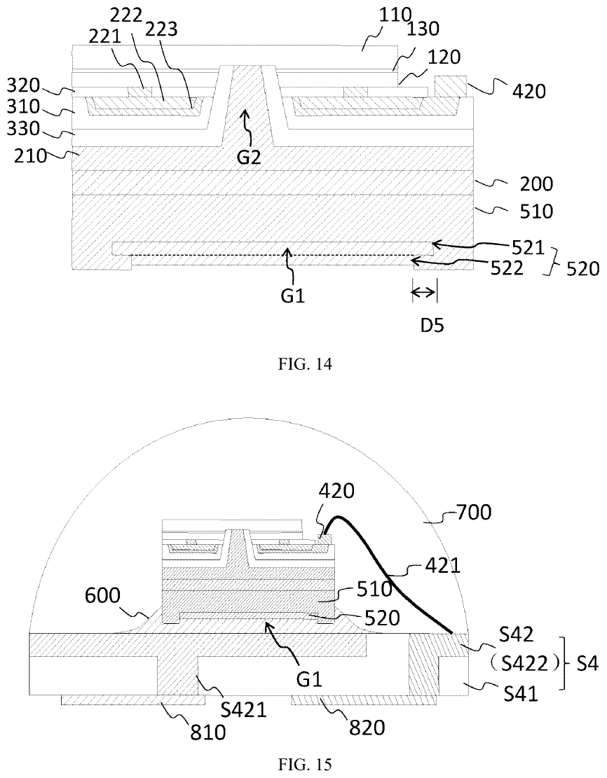

In a sixth embodiment of the disclosure, referring to FIG. 14, a LED is provided. On a basis of the preparation method in the fifth embodiment, the shape of the first metal layer 510 and the second metal layer 520 is further controlled by using the differences in melting points and material properties between the first metal layer 510 and the second metal layer 520. The first metal layer 510 has a first Mohs hardness, and the second metal layer 520 has a second Mohs hardness, and the first Mohs hardness is greater than the second Mohs hardness. A melting point of the first metal layer 510 is higher than a melting point of the second metal layer 520. An edge part of the second metal layer 520 is removed to form a stepped shape with a first part 521 and a second part 522. To clearly describe this, dashed lines are used in FIG. 14 to distinguish between the first part 521 and the second part 522. The first part 521 is disposed on the second part 522, with the area of the first part 521 being greater than that of the second part 522. The back side of the first part 521 is exposed from the second part 522. The first metal layer 510 is disposed to extend from the side of the first part 521 of the second metal layer 520 to the exposed part of the back side of the first part 521, and further extends to the side surface of the second part 522. The first metal layer 510 forms a clip for the second metal layer 520, with parts of the front and back sides of the edge of the second metal layer 520 simultaneously contacting the first metal layer 510. That is, the front and back sides of the edge part of the second metal layer 520 simultaneously contact the first metal layer 510, while a center part of the second metal layer 520 only contacts the back side of the first metal layer 510 on the front side of the second metal layer 520. A width D5 of a part of the first metal layer 510 at the edge of the second metal layer 520 is in a range of 0.1 μm to 5 μm. This design prevents the second metal layer 520 from falling off the back side of the first metal layer 510 during the process, thereby improving product yield. The extension part of the first metal layer 510 is no more than 0.5 μm higher than the first metal layer 510.

The side contact surface between the first metal layer 510 and the second metal layer 520 completely covers the side surface of the second metal layer 520, and extends to cover a part of the back side of the second metal layer 520, an uncovered part of the back side of the second metal layer 520 is exposed.

In a seventh embodiment of the disclosure, referring to FIG. 15, a light-emitting device is provided, adopting the LED in the second embodiment. The light-emitting device includes an encapsulant device, including: a base S4, and the LED bonded on the base S4. The LED includes a metal substrate S1, and a semiconductor layer sequence 100 disposed on the metal substrate S1. The semiconductor layer sequence 100 includes a first semiconductor layer 110, a second semiconductor layer 120 and an active layer 130, and the active layer 130 is disposed between the first semiconductor layer 110 and the second semiconductor layer 120. The LED further includes a first electrode 410 and a second electrode 420. The first electrode 410 is electrically connected to the first semiconductor layer 110. The second electrode 420 is electrically connected to the second semiconductor layer 120. The metal substrate S1 includes a first metal layer 510. A side of the metal substrate S1 facing away the semiconductor layer sequence 100 defines a groove G1. A second metal layer 520 is disposed in the groove G1. Sides of the first metal layer 510 and the second metal layer 520 facing away the semiconductor layer sequence 100 are bonded with the base S4 through a bonding layer 600. The bonding layer 600 is disposed between the second metal layer 520 and the base S4, laid on a surface of the base S4. The first metal layer 510 includes a groove edge G11 which is protruded. The groove edge G11 is no more than 0.1 μm higher than the second metal layer 520. The base S4 includes an insulating support S41 and a conductive support S42. The conductive support S42 includes a first conductive support S421 and a second conductive support S422. The first conductive support S421 and the second conductive support S422 are fixed through the insulating support S41. The LED is disposed on the base S4.

The second metal layer 520 serves as the first electrode 410 and is disposed on the back side of the first metal layer 510. The first electrode 410 is connected to the first conductive support S421 through the bonding layer 600, forming an electrical connection. The second electrode 420 is disposed on the second electrical connecting layer 220, which is exposed after the semiconductor layer sequence 100 and the first insulating layer 310 are partially removed. The second electrode 420 is electrically connected to the second conductive support S422 through a wire 421. In this embodiment, the light-emitting device further includes a cover 700 containing phosphor, but the cover 700 is not a necessary component of this embodiment. In this embodiment, the first conductive support S421 is connected to a first pad 810, and the second conductive support S422 is connected to a second pad 820.

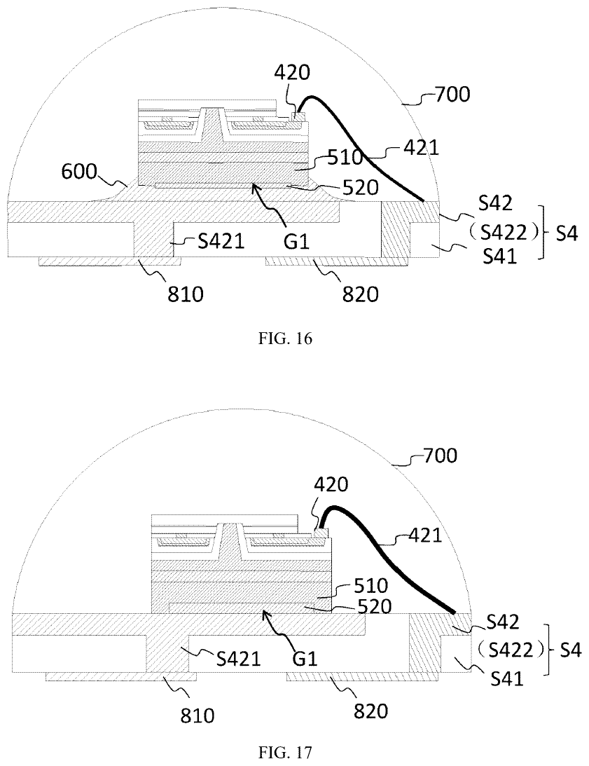

In an eighth embodiment of the disclosure, referring to FIG. 16, a light-emitting device is provided, using the LED in the third embodiment. The light-emitting device provides an encapsulant device, including: a base S4, and the LED bonded on the base S4. The LED includes a metal substrate S1, and a semiconductor layer sequence 100 disposed on the metal substrate S1. The semiconductor layer sequence 100 includes a first semiconductor layer 110, a second semiconductor layer 120 and an active layer 130, and the active layer 130 is disposed between the first semiconductor layer 110 and a second semiconductor layer 120. The LED further includes a first electrode 410 and a second electrode 420. The first electrode 410 is electrically connected to the first semiconductor layer 110, and the second electrode 420 is electrically connected to the second semiconductor layer 120. The metal substrate S1 includes a first metal layer 510. In this embodiment, the first electrode 410 includes the first metal layer 510 and a second metal layer 520. A side of the metal substrate S1 facing away the semiconductor layer sequence 100 defines a groove G1. The second metal layer 520 is disposed in the groove G1. Sides of the first metal layer 510 and the second metal layer 520 facing away the semiconductor layer sequence 100 are bonded with the base S4 through a bonding layer 600. The bonding layer 600 is disposed between the second metal layer 520 and the base S4, laid on a surface of the base S4. The first metal layer 510 includes a groove edge G11 which is protruded. The second metal layer 520 is 0.05 μm to 1 μm higher than the groove edge G11. The second metal layer 520 as the first electrode 410 is disposed at the back side of the first metal layer 510. The base S4 includes an insulating support S41 and a conductive support S42. The conductive support S42 includes a first conductive support S421 and a second conductive support S422. The first conductive support S421 and the second conductive support S422 are fixed through the insulating support S41. The LED is disposed on the base S4. The first electrode 410 is connected to the first conductive support S421 through the bonding layer 600. The bonding layer 600 extends from a bottom of the second metal layer 520 to a side wall of the second metal layer 520, forming an electrical connection.

The second metal layer 520 serves as a part of the first electrode 410 and is disposed on the back side of the first metal layer 510. The first electrode 410 is connected to the first conductive support S421 through the bonding layer 600, forming an electrical connection. The second electrode 420 is disposed on the second electrical connecting layer 220, which is exposed after the semiconductor layer sequence 100 and the first insulating layer 310 are partially removed. The second electrode 420 is electrically connected to the second conductive support S422 through a wire 421. In this embodiment, the light-emitting device further includes a cover 700 containing phosphor, but the cover 700 is not a necessary component of this embodiment.

In a ninth embodiment of the disclosure, referring to FIG. 17, the difference from the sixth embodiment is that a light-emitting device is provided, where the metal substrate S1 is directly bonded directly to the base S4 through the second metal layer 520. In this embodiment, there is no need to use the bonding layer 600 for chip bonding.

In a tenth embodiment of the disclosure, a vehicle lamp is provided, mainly used for automotive lighting or automotive display, which includes any of the light-emitting devices from the sixth embodiment to the eighth embodiment.

It should be noted that the above embodiments are provided to illustrate the technical solutions of the disclosure and are not intended to limit it. Although the disclosure has been described in detail with reference to the above embodiments, those skilled in the art should understand that they can still modify the technical solutions described in the above embodiments, or replace part or all of the technical features with equivalent ones. Such modifications or substitutions do not cause the essence of the corresponding technical solutions to deviate from the scope of the technical solutions of the various embodiments of the disclosure.

What is claimed is:

1. A light-emitting diode (LED), comprising:
a metal substrate, comprising a first metal layer;
a semiconductor layer sequence disposed on the metal substrate, wherein the semiconductor layer sequence comprises a first semiconductor layer, a second semiconductor layer and an active layer, and the active layer is disposed between the first semiconductor layer and the second semiconductor layer;
a first electrode, electrically connected to the first semiconductor layer; and
a second electrode, electrically connected to the second semiconductor layer;
wherein a side of the metal substrate facing away the semiconductor layer sequence defines a groove, a second metal layer is disposed in the groove, the metal substrate comprises a groove edge which is extended, and the groove edge is no more than 0.5 micrometers (μm) higher than the second metal layer.

2. The LED as claimed in claim 1, wherein a height of the groove edge is lower than a height of the second metal layer, and the second metal layer is 0.05 μm to 1 μm higher than the groove edge.

3. The LED as claimed in claim 1, wherein the first metal layer has a first Mohs hardness, the second metal layer has a second Mohs hardness, the first Mohs hardness is greater than the second Mohs hardness, and the second Mohs hardness is in a range of 0.92 to 3.

4. The LED as claimed in claim 1, wherein the first metal layer comprises one or alloy selected from the group consisting of molybdenum, copper, tungsten, iron, aluminum, titanium, nickel and cobalt.

5. The LED as claimed in claim 1, wherein the second metal layer comprises one or alloy selected from the group consisting of gold, gold-tin, indium and tin.

6. The LED as claimed in claim 1, wherein the groove edge of the metal substrate is obtained by laser cutting.

7. The LED as claimed in claim 1, wherein the groove edge comprises the first metal layer, a melting point of the first metal layer is greater than a melting point of the second metal layer, the melting point of the first metal layer is greater than 500 degrees Celsius (° C.), and the melting point of the second metal layer is less than 350° C.

8. The LED as claimed in claim 1, wherein a thickness of the first metal layer is in a range of 80 μm to 200 μm, and a thickness of the second metal layer is in a range of 0.1 μm to 10 μm.

9. The LED as claimed in claim 1, wherein the groove edge is no more than 0.1 μm higher than the second metal layer.

10. The LED as claimed in claim 1, wherein a depth of the groove is in a range of 0.1 μm to 10 μm.

11. The LED as claimed in claim 1, wherein a thickness of the groove edge is in a range of 1 μm to 20 μm.

12. A LED, comprising:
a substrate;
a semiconductor layer sequence disposed on the substrate, wherein the semiconductor layer sequence comprises a first semiconductor layer, a second semiconductor layer and an active layer, and the active layer is disposed between the first semiconductor layer and the second semiconductor layer;
a first electrode, electrically connected to the first semiconductor layer;
a second electrode, electrically connected to the second semiconductor layer; and
a first metal layer, disposed under the substrate;
wherein a side of the first metal layer facing away the semiconductor layer sequence defines a groove, a second metal layer is disposed in the groove, the first metal layer comprises a groove edge which is protruded, and the groove edge is no more than 0.5 μm higher than the second metal layer.

13. The LED as claimed in claim 12, wherein a thickness of the first metal layer is in a range of 0.1 μm to 10 μm, and a thickness of the second metal layer is in a range of 0.1 μm to 10 μm.

14. The LED as claimed in claim 12, wherein the first metal layer has a first Mohs hardness, the second metal layer has a second Mohs hardness, the first Mohs hardness is greater than the second Mohs hardness, and the second Mohs hardness is in a range of 0.92 to 3.

15. The LED as claimed in claim 12, wherein the first metal layer comprises one or alloy selected from the group consisting of molybdenum, copper, tungsten, iron, aluminum, titanium, nickel and cobalt.

16. The LED as claimed in claim 12, wherein the second metal layer comprises one or alloy selected from the group consisting of gold, gold-tin, indium and tin.

17. A LED, comprising:
a metal substrate, comprising: a first metal layer;
a semiconductor layer sequence disposed on the metal substrate, wherein the semiconductor layer sequence comprises a first semiconductor layer, a second semiconductor layer and an active layer, and the active layer is disposed between the first semiconductor layer and the second semiconductor layer;
a first electrode, electrically connected to the first semiconductor layer; and
a second electrode, electrically connected to the second semiconductor layer;
wherein a side of the metal substrate facing away the semiconductor layer sequence is concave inward to define a groove, a second metal layer is disposed in the groove, the groove is concave inward to form a planar contact surface with the second metal layer, a side of the second metal layer close to the metal substrate is a front side, a side of the second metal layer facing away the metal substrate is a back side, and a side surface of the second metal layer is disposed between the front side and the back side; and
wherein the metal substrate comprises a groove edge which is extended, the groove edge and the second metal layer together form a side contact surface, and the planar contact surface and the side contact surface together completely or partially cover the front side and the side surface of the second metal layer.

18. The LED as claimed in claim 17, wherein the side contact surface partially covers the side surface of the second metal layer, and an uncovered part of the side surface of the second metal layer and the back side of the second metal layer are exposed.

19. The LED as claimed in claim 17, wherein the side contact surface completely covers the side surface of the second metal layer, the side contact surface is at a same height as the side surface of the second metal layer, and the back side of the second metal layer is uncovered and exposed.

20. The LED as claimed in claim 17, wherein the side contact surface completely covers the side surface of the second metal layer, and extends to cover a part of the back side of the second metal layer, an uncovered part of the back side of the second metal layer is exposed.
